(19) United States
(12) Patent Application Publication
(10) Pub. No.: US 2009/0177424 A1
(43) Pub. Date: Jul. 9, 2009

(54) 3-Dimensional method for determining the clock-to-Q delay of a flipflop

(76) Inventor: Ronald Pasqualini, Los Altos, CA (US)

Correspondence Address: Law Office Of Mark C. Pickering, P.O. Box 151440, San Rafael, CA, 94915-1440, US

(21) Appl. No.: 12/008,236

(22) Filed: Jan. 8, 2008

(51) Int. Cl. G01R 29/02

(52) U.S. Cl. 702/79

(57) ABSTRACT

A 3-dimensional flipflop timing model is described, which allows a flipflop to be presented with a smaller setup time in comparison to a 2-dimensional timing model. Because of this, fewer timing errors will be encountered during chip timing analysis, fewer timing errors will have to be fixed, and the user can often avoid redesigning logic that fails to meet its timing specs, thus saving valuable design time. Furthermore, in many cases, the user can avoid the necessity of using larger standard cells that employ larger transistor sizes, thus minimizing chip size and chip power dissipation.

### BACKGROUND OF THE INVENTION

1. Field of the Invention.

The present invention relates to flipflops, and more particularly, to a 3-dimensional method for determining the clock-to-Q delay of a flipflop.

2. Description of the Related Art.

FIG. 1 shows a prior-art example of a circuit schematic for a rising-edge-triggered CMOS D flipflop 100. Referring to FIG. 1, flipflop 100 includes a master latch 110, a slave latch 112, and a clock inverter U1. Furthermore, except for the transistor sizes, the circuit topologies of master latch 110 and slave latch 112 are identical. This latch topology consists of two transmission gates and two inverters.

One characteristic of a flipflop is its metastability. As shown in FIG. 1, master latch 110 has a master latch loop 114 that includes an inverter U2, an inverter U3, and a transmission gate X2. Similarly, slave latch 112 has a slave latch loop 116 that includes an inverter U4, an inverter U5, and a transmission gate X4. Furthermore, master latch loop 114 and slave latch loop 116 are both high gain positive feedback loops because they include two high gain inverting components (inverters U2/U3 and inverters U4/U5, respectively), and one non-inverting component (transmission gate X2 and transmission gate X4, respectively).

As a consequence of this, the loops 114 and 116 are bi-stable. In other words, the loops 114 and 116 have two low energy states that are extremely stable, and one high energy state that is extremely unstable (i.e. metastable). The two low energy states for the loops 114 and 116 are represented by the power supply voltage VDD and ground.

FIG. 2 shows a physical analogy of flipflop metastable behavior in terms of an ideal ball that is precariously balanced at a single point on top of an ideal hill. While the ball is precariously balanced on top of the hill, it is in a very high energy state that is extremely unstable. Furthermore, the probability that the ball will remain in this high energy state is extremely low because the ball would have to be perfectly balanced, with absolutely no disturbing forces. Therefore, it is extremely likely that the ball will roll down the hill on one side or the other, exiting its unstable high energy state and entering one of its two, stable, low energy states.

In other words, if the nodes within the master and slave latch loops 114 and 116 are precariously balanced at their metastable voltage levels between the power supply voltage VDD and ground, then the loops 114 and 116 will quickly switch up or down until they reach the power supply voltage VDD or ground. This behavior is a direct result of the high loop gain and positive feedback that are present in the master and slave latch loops 114 and 116.

The time interval during which the master/slave loop nodes remain at their metastable voltage levels is known as the metastability resolution time, Tmeta. For most high performance flipflops, the metastability resolution time Tmeta is infinitesimally small, i.e., on the order of tens of femtoseconds (10⁻¹⁵) or even tens of attoseconds (10⁻¹⁸).

Referring again to FIG. 1, flipflop 100 operates in response to a clock signal CLK and a data signal DIN. When the clock signal CLK input to flipflop 100 is low, master latch transmission gate X1 is in its turned-on state, and master latch transmission gate X2 is in its turned-off state. Furthermore, when the clock signal CLK is low, slave latch transmission gate X4 is in its turned-on state, and slave latch transmission gate X3 is in its turned-off state. Thus, when the clock signal CLK is low, the data signal DIN input to flipflop 100 is connected to the D1 node of master latch 110, and the D1Z output of master latch 110 is disconnected from the D2Z node of slave latch 112.

In addition, when the clock signal CLK is high, master latch transmission gate X1 is in its turned-off state, and master latch transmission gate X2 is in its turned-on state. Furthermore, when the clock signal CLK is high, slave latch transmission gate X4 is in its turned-off state, and slave latch transmission gate X3 is in its turned-on state. Thus, when the clock signal CLK is high, the data signal DIN is disconnected from the D1 node of master latch 110, and the master latch output D1Z is connected to the D2Z node of slave latch 112. As a result of the aforementioned transmission gate states, when the clock signal CLK goes from low to high, the Q output of flipflop 100 can change state, indicating that flipflop 100 is a rising-edge-triggered flipflop.

As shown in FIG. 1, if the data signal DIN input to flipflop 100 remains constant (high or low), then master latch 110 and slave latch 112 will simply retain their current states when the clock signal CLK goes from low to high, or from high to low. In this case, no signal propagation takes place within master latch 110 or slave latch 112 of flipflop 100, and so the flipflop timing parameters are irrelevant. Therefore, in all of the discussions that follow, it is assumed that the output D1Z of master latch 110 always changes state shortly after the clock signal CLK goes from high to low, and the output Q of slave latch 112 always changes state shortly after the clock signal CLK goes from low to high.

In order for flipflop 100 to function correctly, master latch 110 must be able to capture the value of the data signal DIN while the clock signal CLK is low. In addition, master latch 110 must also be able to retain the captured DIN signal value after the clock signal CLK rises. Thus, if the data signal DIN changes its value just before the clock signal CLK rises, master latch 110 may not have enough time to respond (i.e. it may not have enough time to capture the new value of the data signal DIN). Thus flipflop 100 will malfunction when it lacks enough time to capture the new value of the data signal DIN.

Furthermore, when the data signal DIN has been present for a long time while the clock signal CLK is low, master latch 110 will correctly capture this “old” signal value. Nevertheless, this correctly captured “old” signal value must still be transferred to slave latch 112 when the clock signal CLK rises. However, if the data signal DIN changes from its “old” value to a “new” value just before, or just after, the clock signal CLK rises, master latch 110 may respond to the “new” DIN signal value and ignore the “old” DIN signal value. In this case, the “old” DIN signal value is not transferred to slave latch 112, resulting in a flipflop malfunction.

In summary, in order for a flipflop to function correctly, the data signal DIN must be stable (non-changing) during a time interval before the clock signal CLK rises, which is known as the setup time, and during a time interval after the clock signal CLK rises, which is known as the hold time.

FIGS. 3A-3C show timing diagrams that illustrate timing parameters related to the operation of a flipflop. As shown in FIGS. 3A-3C, the data signal DIN must be valid (non-changing) during the setup time for the flipflop, Tsetup. In addition, the data signal DIN must also be valid (non-changing) during the hold time for the flipflop, Thold. When these conditions are satisfied, the flipflop output Q will be able to correctly change state after the rising edge of the clock signal CLK.

However, if the data signal DIN changes state during the setup time interval Tsetup, or during the hold time interval Thold, then master latch 110 may not be able to capture the correct value of the data signal DIN, resulting in a flipflop malfunction. Furthermore, the setup time and the hold time only depend upon the circuit characteristics of the master latch, not the slave latch. In other words, the setup and hold times do not depend upon the load capacitance being driven by the flipflop output Q.

Although a flipflop requires a specified minimum setup time in order to function correctly, in most applications the flipflop is presented with additional setup time, beyond its specified minimum setup time. This additional setup time is often referred to as “setup slack time”, or simply as “setup slack”.

In addition, although a flipflop requires a specified minimum hold time in order to function correctly, in most applications the flipflop is presented with additional hold time, beyond the specified minimum hold time. This additional hold time is often referred to as “hold slack time” or simply as “hold slack”.

FIGS. 4A-4C show timing diagrams that illustrate several timing parameters for a flipflop. Thus, as shown in FIG. 4A, the setup time Tsetup, and the setup slack time Tsetup_slack, are illustrated. Furthermore, the hold time Thold, and the hold slack time Thold_slack, are also illustrated. As stated above, when the setup time Tsetup and the hold time Thold have been satisfied, the flipflop output Q will be able to correctly change state after the rising edge of the clock signal CLK.

As illustrated in FIG. 4A, the setup time (Tsetup), hold time (Thold), setup slack time (Tsetup_slack), and the hold slack time (Thold_slack) are all positive in value. Moreover, in many applications, the values of these parameters will actually be positive (as they are defined in FIG. 4A). Nevertheless, since each one of the these parameters can have a negative value, the positive and negative definitions of these parameters are required.

The setup time Tsetup will be positive if the data signal DIN remains stable before the clock signal CLK rises. (Almost all flipflops require positive setup time). The setup time Tsetup will be negative if the data signal DIN changes after the clock signal CLK rises. If the setup time Tsetup becomes negative, the flipflop will malfunction unless the clock signal CLK is intentionally delayed inside of the flipflop, making the actual setup time for the master latch loop positive. Nevertheless, most flipflops are not designed to deal with negative setup time.

The hold time Thold will be positive if the data signal DIN remains stable after the flipflop clock signal CLK rises. The hold time Thold will be negative if the data signal DIN changes before the clock signal CLK rises. Most flipflops, including flipflop 100 shown in FIG. 1, will function correctly if they are presented with a hold time Thold that is slightly negative. In other words, if the “old” DIN value to be captured changes just before the rising edge of the clock signal CLK, the “old” DIN value will still be captured correctly. This behavior occurs because the data signal DIN is slightly delayed by transmission gate X1, delaying the effect of DIN voltage changes upon the state of the master latch loop. Thus, if the “old” DIN value is changed slightly before the clock signal CLK rises, the “old” DIN value may still be captured correctly if the master latch loop is not fast enough to respond to the “new” DIN value.

FIGS. 5A-5C show timing diagrams that further illustrate several timing parameters for a flipflop. As shown in FIGS. 5A-5C, positive setup times Tsetup_1 and Tsetup_2 are illustrated. In addition, a positive hold time Thold_1 is illustrated, and a negative hold time Thold_2 is also illustrated. Referring to FIGS. 5A-5C, it can be seen that near the first rising clock edge CLK1, the data signal is labeled DIN_1. As shown in FIGS. 5A-5C, the data signal DIN_1 presents a positive setup time Tsetup_1, and a positive hold time Thold_1, to the flipflop. As a consequence of this, the flipflop output Q correctly changes state from Q_0 to Q_1, after the rising edge of the CLK1 pulse.

Again referring to FIGS. 5A-5C, it can be seen that near the second rising clock edge CLK2, the data signal is labeled DIN_2, which presents a positive setup time Tsetup_2, and the negative hold time Thold_2, to the flipflop. However, since the negative hold time Thold_2 is small, the flipflop output Q correctly changes state from Q_1 to Q_2, after the rising edge of the CLK2 pulse. On the other hand, if the hold time Thold_2 in FIGS. 5A-5C is made too negative, the flipflop output Q will capture the “new” data signal DIN_3, instead of the “old” data signal DIN_2, resulting in a flipflop malfunction.

The setup slack time will be positive if a flipflop is presented with setup time that exceeds its minimum required setup time. Moreover, the setup slack time will be negative if a flipflop is presented with setup time that is less than the minimum required setup time. Similarly, the hold slack time will be positive if a flipflop is presented with a hold time that exceeds its minimum required hold time. Moreover, the hold slack time will be negative if a flipflop is presented with a hold time that is less than the minimum required hold time.

Again referring to FIG. 1, in order for flipflop 100 to function correctly, slave latch loop 116 must capture the value on the D1Z output of master latch 110, when the clock signal CLK rises. Furthermore, if the low time of the clock signal CLK is of adequate duration, this will happen automatically because the D1Z signal will be in a stable state when the clock signal CLK rises.

As previously discussed, the Q output of a leading edge triggered flipflop can change state shortly after the clock signal CLK rises. However, before the Q output can change state, the value on the D1Z output of master latch 110 must first propagate through transmission gate X3 of slave latch 112, in order to drive the D2Z input of slave latch inverter U4. In addition, slave latch inverter U4 must also drive the capacitance connected to the Q output of flipflop 100.

The propagation delay associated with the above signal path is known as the clock-to-Q propagation delay, or simply as the clock-to-Q time. As discussed above, the value of the clock-to-Q propagation delay depends upon the internal delays within slave latch 112. However, the clock-to-Q propagation delay also depends upon the external load capacitance connected to the Q output of the flipflop. This external load capacitance has two sources: the input capacitance of the external logic gates that are being driven by the flipflop, and the wire capacitance necessary to connect the Q output of the flipflop to the external logic gates that are being driven. If the flipflop external load capacitance is small, the clock-to-Q propagation delay will be small, and it will mainly depend upon the internal propagation delays within the flipflop (i.e. within slave latch 112). Conversely, if the flipflop external load capacitance is large, the clock-to-Q propagation delay will be large, and it will mainly depend upon the external load capacitance being driven by the flipflop.

In addition to the above clock-to-Q delay, the timing performance of a flipflop, such as flipflop 100, can also be characterized in terms of its output risetime Tr, and its output falltime Tf. Although the output risetime and falltime are often different in value, these parameters are usually lumped together and referred to as ‘Trf’.

FIG. 6 shows a logic diagram that illustrates an example of a prior-art logic circuit 600. As shown in FIG. 6, logic circuit 600 includes a first rising-edge-triggered flipflop U1 that has a data input D, a clock input CK, and a non-inverting output Q. Furthermore, a capacitor C1, which represents the total capacitance that the Q output must drive, is connected to the Q output of flipflop U1.

Logic circuit 600 also includes a first NAND gate U2 that has a first input connected to the Q output of flipflop U1, a second input connected to a logic high, and a third input connected to a logic high. In addition, a capacitor C2, which represents the total capacitance that NAND gate U2 must drive, is connected to the output of NAND gate U2.

As further shown in FIG. 6, logic circuit 600 also includes a second NAND gate U3 that has a first input connected to a logic high, a second input connected to the output of NAND gate U2, and a third input connected to a logic high. In addition, a capacitor C3, which represents the total capacitance that NAND gate U3 must drive, is connected to the output of NAND gate U3.

As shown in FIG. 6, logic circuit 600 additionally includes a second rising-edge-triggered flipflop U4 that has a data input D connected to the output of NAND gate U3, a clock input CK connected to the clock input CK of flipflop U1, and a non-inverting output Q. Furthermore, a capacitor C4, which represents the total capacitance that the Q output must drive, is connected to the Q output of flipflop U4.

Moreover, logic circuit 600 also includes a third NAND gate U5 that has a first input connected to the Q output of flipflop U4, a second input connected to a logic high, and a third input connected to a logic high. In addition, a capacitor C5, which represents the total capacitance that NAND gate U5 must drive, is connected to the output of NAND gate U5.

In addition, logic circuit 600 includes a third rising-edge-triggered flipflop U6 that has a data input D connected to the output of NAND gate U5, a clock input CK connected to the clock input CK of flipflop U1, and a non-inverting output Q. Furthermore, a capacitor C6, which represents the total capacitance that flipflop U6 must drive, is connected to the Q output of flipflop U6.

If the data value on the Q output of flipflop U1 is a logic low, and if the data value on input D of flipflop U1 is a logic high, and if the setup time, hold time, and clock high time requirements of flipflop U1 are being met, then a rising edge on the flipflop U1 clock input CK will cause the Q output of flipflop U1 to generate a logic high, after a clock-to-Q propagation delay TD1.

Furthermore, as shown in FIG. 6, the low to high transition on the Q output of flipflop U1 will then cause the output of NAND gate U2 to go from a logic high to a logic low, after a propagation delay TD2 of NAND gate U2. Moreover, the high to low transition on the output of NAND gate U2 will then cause the output of NAND gate U3 to go from a logic low to a logic high, after a propagation delay TD3 of NAND gate U3.

Thus, when the clock input CK of flipflop U1 rises, the data signal provided to the data input of flipflop U4 will rise a propagation delay time later, where the propagation delay time is defined as the clock-to-rising-Q propagation delay TD1 of flipflop U1, plus the output falling propagation delay TD2 of NAND gate U2, plus the output rising propagation delay TD3 of NAND gate U3.

In the FIG. 6 example, a timing analysis must be performed in order to ensure that the data signal on the D input of flipflop U4 satisfies the minimum setup time required by flipflop U4. This timing analysis is required in order to ensure that flipflop U4 will be able to correctly capture the data value on its D input, on the next rising edge of its CK clock input. Thus the total setup time Tsetup_U4, that is provided to flipflop U4 before the next rising edge of the clock signal CLK, is defined by equation EQ. 1 below.

Tsetup_U4=Tclk−TD1−TD2−TD3 Eq. 1

where Tclk represents the period of the clock signal.

For illustrative purposes, assume that the clock period is equal to 2 ns. In a first case, if the total propagation delay (TD1+TD2+TD3) is equal to 0.40 ns, then the setup time presented to flipflop U4 will be equal to 1.60 ns (2ns−0.4ns). Thus, if the setup time required by flipflop U4 is 1.5 ns, then flipflop U4 will be provided with a positive setup slack time of 0.1 ns (1.6ns−1.5ns).

In a second case, if the total propagation delay (TD1+TD2+TD3) is equal to 0.50 ns, then the setup time presented to flipflop U4 will be equal to 1.5 ns (2ns−0.5ns). Thus, if the setup time required by flipflop U4 is again equal to 1.5 ns, then flipflop U4 will be provided with a setup slack time of 0 ns (1.5ns−1.5ns). As a result, in cases 1 and 2 above, flipflop U4 will correctly capture the value of the data signal on its data input D, even though zero setup slack time is provided in case two. In both cases, the data will be captured on the next rising edge of the clock signal CLK (assuming that the hold time and clock high time requirements for flipflop U4 have also been met).

In a third case, if the total propagation delay (TD1+TD2+TD3) is equal to 0.70 ns, then the setup time presented to flipflop U4 will be equal to 1.30 ns (2ns−0.7ns). Thus, if the setup time required by flipflop U4 is again equal to 1.5 ns, then flipflop U4 will be provided with a setup slack time of −0.2 ns (1.3ns−1.5ns). Therefore, since the setup slack time is negative, logic circuit 600 will malfunction. In other words, logic circuit 600 will malfunction because the setup time actually presented to flipflop U4 is less than the (minimum) setup time required by flipflop U4.

In the prior art, the propagation delay through a standard cell logic gate, from input-pin-to-output-pin, is often determined by employing a 2-dimensional table lookup and interpolation technique. This technique utilizes output pin load capacitance, input pin risetime and input pin falltime as input variables, and computes input-pin-to-output-pin propagation delay, output pin risetime, and output pin falltime as output variables. Thus, before this technique can be employed, a propagation delay database for each standard cell must first be constructed. Furthermore, this propagation delay database is usually constructed by performing a large number of parametric circuit simulations, and then tabulating the resulting propagation delays in table format, where they can be quickly looked up and interpolated. In other words, a large number of circuit simulations must first be performed, in which each of the input variables that affect propagation delay are systematically stepped over a range of values, in appropriate increments.

For example, since the propagation delay of a logic gate depends upon the external load capacitance being driven by the logic gate output, the following values of output pin load capacitance might be simulated: 0 ff, 0.1 ff, 0.3 ff, 0.7 ff, 1.0 ff, 10 ff, 100 ff, 1000 ff. Furthermore, since the propagation delay of a logic gate also depends upon the rise/fall time on each logic gate input pin, the following input pin rise/fall times might be simulated: 0.1 ns, 0.2 ns, 0.4 ns, 0.6 ns, 0.8 ns, 1.0 ns, 3 ns, 10 ns. Thus, since there are 8 different values for output pin load capacitance and 8 different values for input pin rise/fall times, the total number of parametric cases to be simulated is equal to 8×8×2=128 cases.

However, since the propagation delay of a logic gate also depends upon PVT (process/voltage/temperature) conditions, the user might choose to employ at least three different values (e.g. min/typ/max values) for each of the PVT variables, for a total of 3×3×3=27 different PVT cases. Thus, when the 27 PVT cases are combined with the aforementioned 128 parametric cases, the total number of cases that must be simulated, for a single standard cell, is equal to 128×27=3,456 cases. Of course, since all of these cases must be simulated for each logic gate in a standard cell library, and a given standard cell library can easily contain a hundred or more standard cells, the total number of circuit simulations that must be performed, in order to completely characterize a standard cell library, can easily reach a few hundred thousand simulations.

In the prior art, the 2-dimensional delay model described above is often referred to as a “2-dimensional, non-linear, table lookup model” because, excluding the PVT parameters, it only employs two input variables (output pin load capacitance and input pin rise/fall time), in order to calculate two output variables (input-pin-to-output-pin propagation delay and output pin rise/fall time).

As described above, the prior art 2-dimensional delay model calculates the input-pin-to-output-pin delay of a standard cell as a function of two input parameters: the standard cell output pin load capacitance and the standard cell input pin rise/fall time. Therefore, since the input pin rise/fall time is required, the model also calculates output pin rise/fall time, since this time serves as the input pin rise/fall time for the next logic gate in a chain of logic gates.

As described above, the prior art 2-dimensional delay model employs interpolation techniques in order to calculate standard cell input-pin-to-output-pin delay and standard cell output pin rise/fall time. Thus interpolation is usually required because the values of the input variables (output pin load capacitance and input pin rise/fall time) will rarely match the exact input variable values stored in the delay database.

The values of the input variables that are stored in the delay database must be carefully chosen, in order to minimize interpolation error. In other words, more input points should be allocated in those regions where the input-pin-to-output-pin propagation delay and the output pin rise/fall time change rapidly.

The clock-to-Q propagation delay of a standard cell rising-edge-triggered flipflop is a function of many parameters, including the setup time presented to the flipflop, the risetime on the flipflop clock input pin, and the total capacitance on the flipflop Q output pin. In addition, other circuit parameters also affect the clock-to-Q propagation delay, including the high time and low time of the flipflop clock signal, the PVT (process, voltage, and temperature) conditions, the sizes of the transistors used inside of the flipflop, and the wire capacitances and resistances inside of the flipflop. Moreover, the risetime and falltime on the flipflop Q output pin are also a function of these same parameters.

Using the prior art 2-dimensional timing model, the clock-to-Q delay of a standard cell flipflop can be obtained in exactly the same way as the input-pin-to-output-pin delay of a standard cell logic gate. Similarly, the output risetime and falltime of a standard cell flipflop can also be obtained in exactly the same way as the output risetime and falltime of a standard cell logic gate. For example, referring to FIG. 6, a timing analysis of logic circuit 600 can be performed, as follows.

As an initial step, the clock-to-Q propagation delay TD1, of standard cell flipflop U1, must first be determined. In order to determine the clock-to-Q propagation delay TD1, the values of the following two parameters must be utilized: the risetime of the clock input signal (S1), and the value of capacitor C1. These two parameter values can then be used to look up and interpolate the clock-to-Q propagation delay TD1, in the flipflop timing database. In addition, the risetime (S2), on the flipflop Q output pin, can also be looked up and interpolated.

Following this, the propagation delay TD2 of NAND gate U2 must next be determined. In order to determine the propagation delay TD2, the values of the following two parameters must be utilized: the risetime (S2) on the Q output pin of flipflop U1, and the value of capacitor C2. These two parameter values can then be used to look up and interpolate the propagation delay TD2, in the NAND gate timing database. In addition, the falltime (S3), on the output pin of NAND gate U2, must also be looked up and interpolated.

Following this, the propagation delay TD3 of NAND gate U3 must next be determined. In order to determine the propagation delay TD3, the values of the following two parameters must be utilized: the falltime (S3) on the output pin of NAND gate U2, and the value of capacitor C3. These two parameter values can then be used to look up and interpolate the propagation delay TD3, in the NAND gate timing database. In addition, the risetime (S4), on the output pin of NAND gate U3, must also be looked up and interpolated.

Finally, the setup time presented to standard cell flipflop U4 can be calculated by utilizing EQ. 1 above. However, if the setup time presented to flipflop U4 is less than the minimum required setup time for flipflop U4, the flipflop timing analysis will fail. In this case, the circuit shown in FIG. 6 must be modified in order to increase the setup time presented to flipflop U4. For example, larger standard cells can be used for U1, and/or U2 and/or U3, in order to reduce TD1, and/or TD2 and/or TD3. As shown by EQ. 1, this will increase the setup time presented to flipflop U4.

However, in many cases, utilizing larger standard cells may not work, and thus the logic circuitry shown in FIG. 6 will have to be completely re-designed. Furthermore, the use of larger standard cells will increase the chip area and the chip power dissipation, which is highly undesirable.

### BRIEF DESCRIPTION OF THE DRAWINGS

FIG. 1 is the circuit schematic for a prior-art rising-edge-triggered CMOS D flipflop 100.

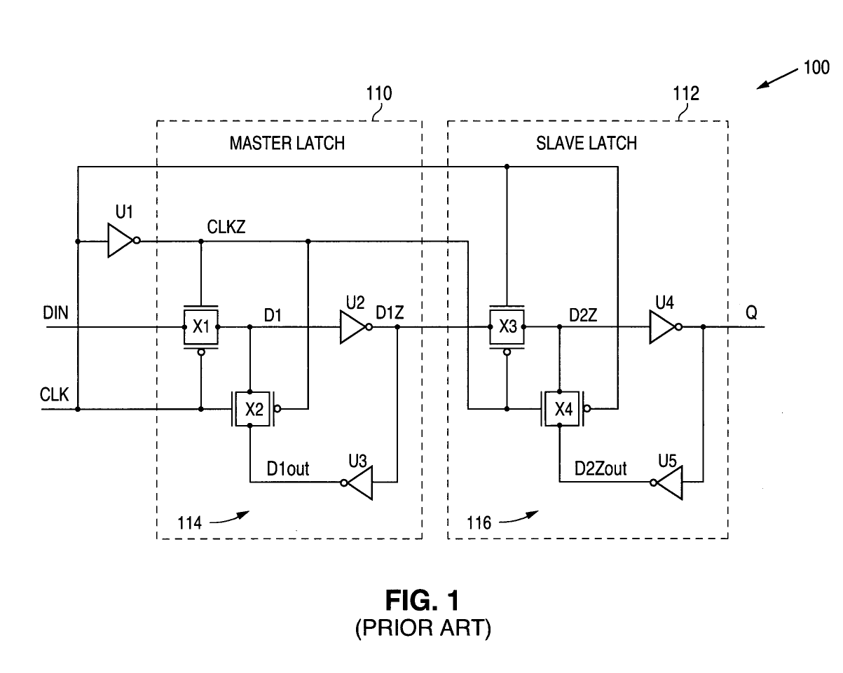

FIG. 2 is a prior-art physical analogy of flipflop metastable behavior in terms of an ideal ball that is precariously balanced at a single point on top of an ideal hill.

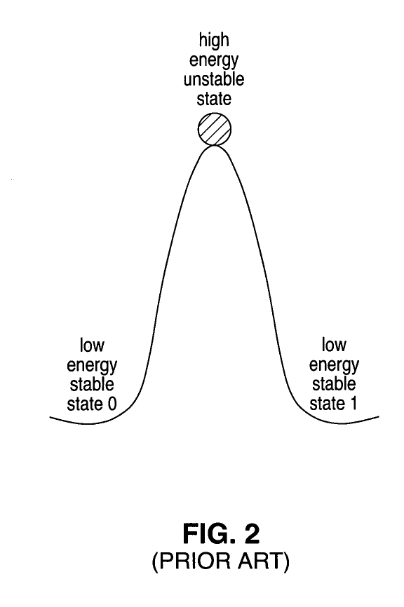

FIGS. 3A-3C are timing diagrams that illustrate the timing parameters of a prior-art flipflop.

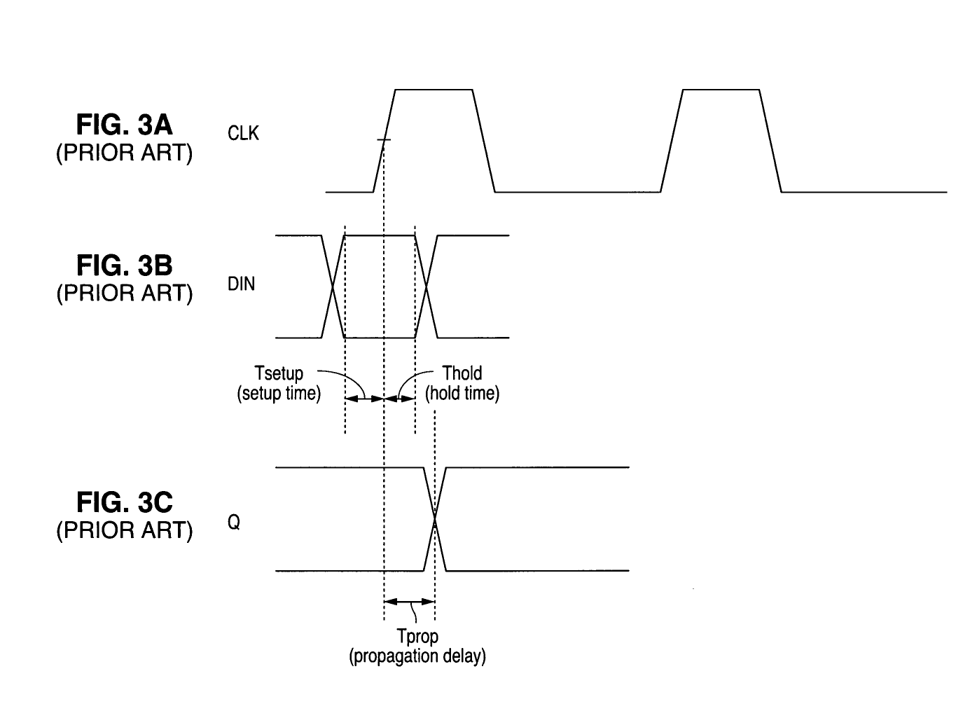

FIGS. 4A-4C are timing diagrams that further illustrate the timing parameters of a prior-art flipflop.

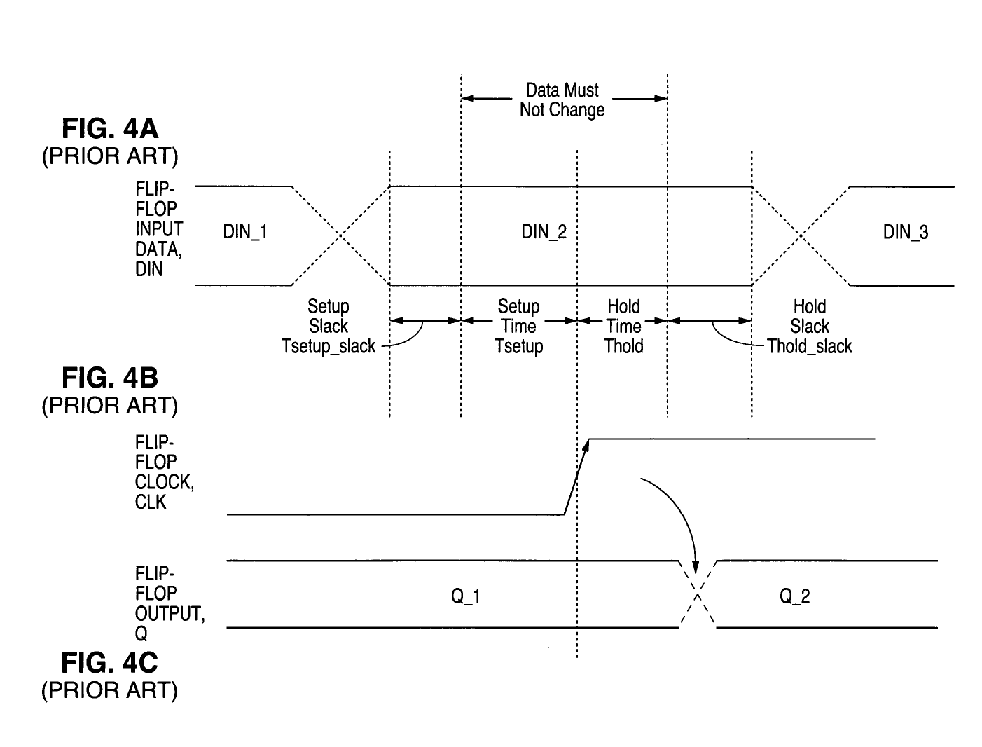

FIGS. 5A-5C are timing diagrams additionally illustrate the timing parameters of a prior-art flipflop.

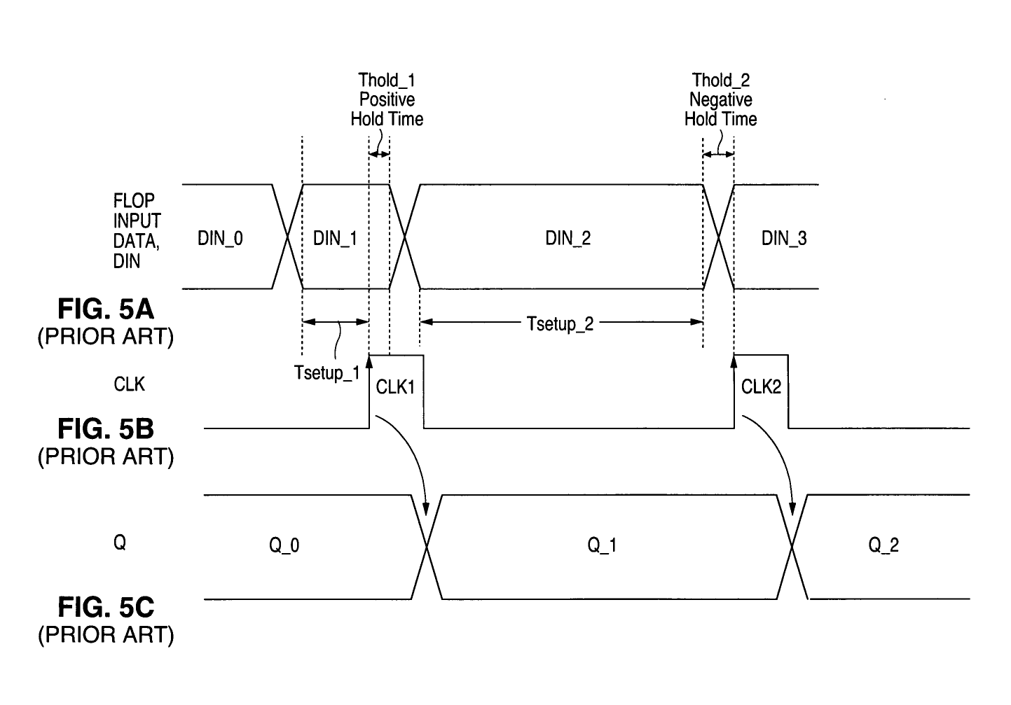

FIG. 6 is a logic diagram illustrating a prior-art example of a logic circuit 600.

FIG. 7 is a graph illustrating an example of the clock-to-Q propagation delay of a rising-edge-triggered flipflop, as a function of the setup time that is presented to the flipflop, and the total load capacitance that must be driven by the Q output of the flipflop, in accordance with the present invention.

FIG. 8 is a flowchart illustrating a method 800 of forming a clock-to-rising Q delay database, in accordance with the present invention.

FIG. 9 is a graph further illustrating the graph shown in FIG. 7, in accordance with the present invention

FIG. 10 is a flow chart illustrating an example of a method 1000 of determining the clock-to-Q delay of a flipflop, in accordance with the present invention.

FIG. 11 is a block diagram illustrating an example of a computer 1100, in accordance with the present invention.

### DETAILED DESCRIPTION OF THE INVENTION

The timing analysis accuracy required for most CMOS chips is usually in the range of 2% to 5%. Therefore, when flipflop clock-to-Q delay is calculated using any given timing model, the clock-to-Q delay should be accurate to within 2% to 5%.

In the above timing example, the prior art 2-dimensional timing model for a standard cell logic gate was utilized in order to calculate the clock-to-Q delay of a standard cell flipflop. However, as described in greater detail below, applying this 2-dimensional timing model forces the user to artificially increase a key flipflop timing specification: the minimum setup time required by the flipflop. Of course, artificially increasing the minimum required setup time is highly disadvantageous because it increases the difficulty of satisfying the timing requirements of any logic circuit that contains flipflops.

Furthermore, increasing the minimum required setup time may make a flipflop totally un-useable in high speed logic applications, where the clock period is very short. This is true because a longer minimum setup time will consume a larger portion of the short clock period.

Thus, the minimum setup time required by a flipflop is an extremely important timing parameter. Therefore, if the user is forced to make the minimum setup time larger than necessary (i.e. excessively large), the user will encounter several important design disadvantages. The first disadvantage is that, when performing a chip timing analysis, the setup time presented to a given flipflop may be less than the excessively large minimum setup time required by the flipflop. In this case, the user may have to re-design a portion of the chip, and/or increase the sizes of certain on-chip logic gates, which often results in increased chip size and increased chip power dissipation.

Furthermore, in high speed applications where the clock period is very short, an excessively large minimum setup time may make a flipflop totally un-useable. This is true because the excessively large minimum setup time can easily consume a disproportionately large portion of the short clock period.

As stated above, utilizing the prior-art 2-dimensional timing model to calculate flipflop clock-to-Q delay forces the user to artificially increase the minimum setup time required by a flipflop. Therefore, the reasons that mandate this highly undesirable increase in the minimum flipflop setup time will now be described.

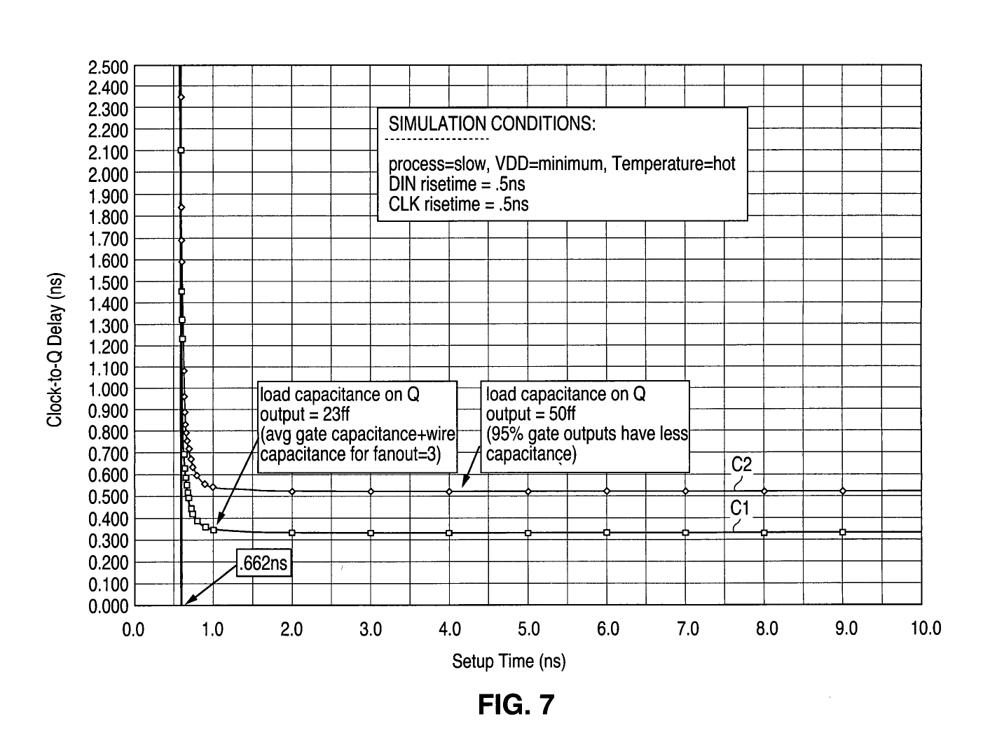

FIG. 7 shows a graph that illustrates an example of the clock-to-Q delay of a flipflop, as a function of the setup time that is presented to the flipflop, and the total load capacitance that must be driven by the Q output of the flipflop, in accordance with the present invention. Referring to FIG. 7, two curves, C1 and C2, are shown. Both curves are plotted for the flipflop Q output rising, under slow PVT conditions.

Slow PVT conditions include slow process, minimum VDD voltage and hot temperature, which result in the longest clock-to-Q delay. Therefore, if the flipflop clock-to-Q delay is fast enough under slow PVT conditions, it will be fast enough under all other PVT conditions.

Referring to FIG. 7, curves C1 and C2 both assume that the risetime of the flipflop clock input is equal to 0.5 ns. Therefore, the only difference between the two curves is that the C1 curve assumes that the load capacitance on the flipflop Q output pin is equal to 23 ff, while the C2 curve assumes that the load capacitance on the flipflop Q output pin is equal to 50 ff.

As shown in FIG. 7, the 23 ff capacitance value represents the average load capacitance being driven by a flipflop, for an average gate fanout of three. Therefore, this 23 ff capacitance value includes the input capacitance of the three logic gates that are being driven, plus the wire capacitance needed to connect these three logic gates to the flipflop Q output.

Again referring to FIG. 7, the 50 ff capacitance value represents a worst case load capacitance, which is greater than the load capacitance being driven by 95% of the flipflops on a given CMOS chip. Therefore, this load capacitance includes the input capacitances of logic gates that are being driven, plus the wire capacitance needed to connect the driven logic gates to the flipflop Q outputs.

As shown in FIG. 7, for curve C1, all of the setup times that are greater than 2 ns produce the same clock-to-Q delay time, namely a value of 0.332 ns. Furthermore, when the setup time is decreased from 2 ns to 1 ns, the clock-to-Q delay only increases from 0.332 ns to 0.346 ns, an increase of approximately 4%. Therefore, to within a good approximation, if the setup time presented to the flipflop is greater than 1 ns, the clock-to-Q delay will not depend upon the presented setup time. In other words, excluding PVT variations, the clock-to-Q delay will only depend upon two parameters: the risetime on the flipflop clock input pin (0.5 ns in the current example), and the load capacitance on the flipflop Q output pin (23 ff in the current example).

Again referring to FIG. 7, for curve C2, all of the setup times that are greater than 2 ns produce the same clock-to-Q delay time, namely a value of 0.520 ns. Furthermore, when the setup time is decreased from 2 ns to 1 ns, the clock-to-Q delay only increases from 0.520 ns to 0.539 ns, an increase of approximately 4%. Therefore, to within a good approximation, if the setup time presented to the flipflop is greater than 1 ns, the clock-to-Q delay will not depend upon the presented setup time. In other words, excluding PVT variations, the clock-to-Q delay will only depend upon two parameters: the risetime on the flipflop clock input pin (0.5 ns in the current example), and the load capacitance on the flipflop Q output pin (50 ff in the current example).

The flipflop clock-to-Q timing model described above is exactly identical to the prior-art logic gate timing model discussed in previous paragraphs. This is true because, excluding PVT variations, the above clock-to-Q timing model only depends upon an input risetime and an output load capacitance, just like the logic gate timing model.

In other words, the above clock-to-Q timing model only depends upon the values of the following two parameters: the risetime on the flipflop clock input pin (0.5 ns in the current examples), and the load capacitance on the flipflop Q output pin (23 ff and 50 ff in the current examples).

Furthermore, the above clock-to-Q timing model is only valid because, as shown in FIG. 7, the clock-to-Q delay curves are effectively flat for all setup time values that are greater than 1 ns. Of course, this flatness satisfies a key assumption of the prior-art clock-to-Q timing model, namely that the clock-to-Q delay is independent of the setup time presented to the flipflop.

Based upon the above discussion, the prior-art clock-to-Q timing model completely ignores flipflop setup times that are less than 1 ns. However, as shown in FIG. 7, the flipflop will function correctly, even when the presented setup time is less than 1 ns.

Referring to the C1 curve in FIG. 7, it can be seen that when the setup time presented to the flipflop is decreased from 1 ns to 0.622 ns, the flipflop will not be able to capture the data signal DIN that is input to the flipflop. In other words, the clock-to-Q delay will increase from 0.332 ns to infinity, effectively resulting in a flipflop timing failure.

Referring to FIG. 7, it can be seen that, as the setup time presented to the flipflop is decreased down to 0.622 ns, the C1 and C2 curves merge together. In other words, the clock-to-Q delay for the C1 and C2 curves becomes the same, even though these curves have different load capacitances. This behavior is to be expected, however, because as the setup time presented to the flipflop is decreased to 0.622 ns, a major portion of the clock-to-Q delay will be due to the metastable resolution time of the master latch. In other words, the clock-to-Q delay for the C1 and C2 curves becomes the same because the metastable resolution time of the master latch does not depend upon the load capacitance that is attached to the Q output pin of the slave latch.

A very important limitation of the prior-art clock-to-Q timing model is that it cannot be used to calculate the clock-to-Q delay, for setup times that are less than 1 ns. This can be seen from the following example.

Using the C1 curve in FIG. 7, if the prior-art clock-to-Q timing model were to allow a setup time of 0.7ns instead of 1 ns, the actual clock-to-Q delay would increase from 0.332 ns to 0.501 ns. However, since the prior-art clock-to-Q timing model is constrained to operate on the flat portion of the clock-to-Q delay curves, it cannot generate a clock-to-Q delay of 0.501 ns. This is true because the 0.501 ns clock-to-Q delay lies on the rising (non-flat) portion of the clock-to-Q delay curves. Therefore, the prior-art clock-to-Q timing model is constrained to generate a clock-to-Q delay of 0.332 ns, which is considerably less than the actual clock-to-Q delay of 0.501 ns. Of course, this less conservative (i.e. faster) clock-to-Q delay could easily cause a true timing violation, resulting in a chip timing failure.

Therefore, in accordance with the present invention, all portions of the flipflop clock-to-Q delay curves can be utilized, including the rising and flat portions, by employing a 3-dimensional timing model for calculating flipflop clock-to-Q delay, instead of employing a prior-art 2-dimensional timing model for calculating flipflop clock-to-Q delay.

Moreover, as noted above, the present invention utilizes a 3-dimensional flipflop database, in lieu of a conventional 2-dimensional flipflop database, to calculate flipflop clock-to-Q delay. Thus, for any given flipflop circuit, and for specified PVT conditions, specified transistor sizes and specified wire resistances/capacitances, the present invention can calculate flipflop clock-to-Q delay by utilizing three input parameters: the slope of the rising clock edge on the flipflop clock input pin, the load capacitance on the flipflop Q output pin, and the setup time presented to the flipflop.

As previously discussed, the first two input parameters are exactly the same as the two input parameters used to access the prior-art flipflop database. The only difference is that the new flipflop database contains a third input parameter: the setup time that is presented to the flipflop. In equation terms, the clock-to-Q delay time, Tprop, can be expressed by equation EQ. 2 as follows.

Tprop=f(Trclk, Cload, Tsetup-p), EQ. 2

where Trclk is the clock risetime, Cload is the total capacitance on the flipflop Q output pin, Tsetup-p is the setup time presented to the flipflop, and f ( . . . ) represents a function that determines the value of Tprop.

The function f ( . . . ) above is a 3-dimensional (3D) function because it accepts three input variables: Trclk, Cload and Tsetup-p. Furthermore, the function f ( . . . ) can be specified as a 3D lookup table. Thus, for any specified values of the table input variables Trclk, Cload and Tsetup-p, the value of Tprop can be looked up and interpolated from the values stored in the table.

As described above, the 3D lookup table that specifies the value of Tprop can be constructed by performing a number of flipflop circuit simulations, using a number of carefully selected discrete values for each of the three input variables (Trclk, Cload and Tsetup-p).

Furthermore, the aforementioned circuit simulations can be performed under a number of different PVT (process/voltage/temperature) conditions. For example, Tprop can be tabulated under slow, typical, and fast process conditions; minimum, typical, and maximum power supply voltages; and cold, typical, and hot temperature conditions.

The above PVT conditions can be combined to form a number of different corner cases, such as the 3×3×3=27 corner cases specified above. In this case, there would be 27 different tables for computing clock-to-Q delay.

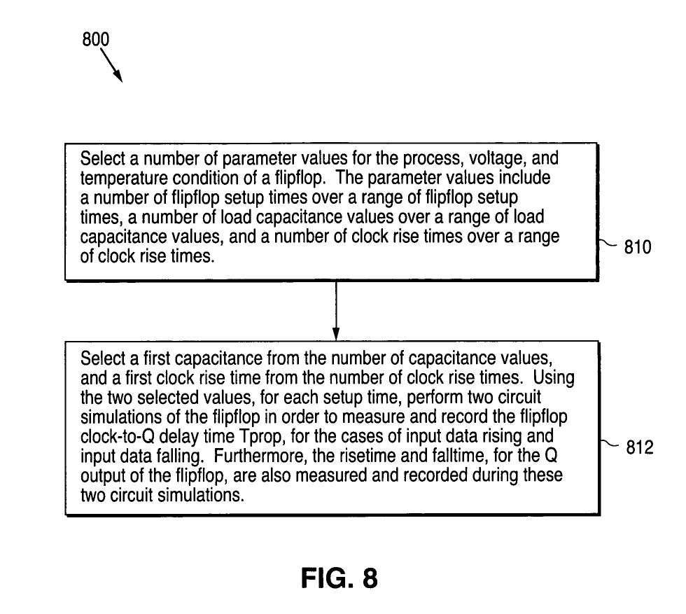

In accordance with the present invention, FIG. 8 illustrates a method 800 of forming a database containing flipflop clock-to-Q delay, and flipflop output risetime/falltime, for a flipflop that is comprised of fixed transistor sizes, parasitic capacitances and parasitic wire resistances.

As shown in FIG. 8, method 800 begins at 810, where a number of parameter values are selected for the process, voltage and temperature conditions of a flipflop, and the clock-to-Q delay of the flipflop is then characterized as a function of these parameter values.

The parameter values also include a number of flipflop setup times over a range of flipflop setup times. The smallest setup time in the range of setup times is the minimum flipflop setup time, which is the setup time at which the flipflop fails to change state within a specified time period (such as 2.5 ns, for example). Thus, as shown in the FIG. 7 example, the minimum flipflop setup time is equal to 0.622 ns, because the flipflop requires more than 2.5 ns to change state when the setup time is decreased to 0.622 ns.

The largest setup time in the range of setup times is the setup time for which the flipflop clock-to-Q delay does not increase, beyond a specified percentage amount (for example 4 percent), when the flipflop setup time is reduced from a first setup time value to a second setup time value.

Thus, as shown in the FIG. 7 example, when the flipflop setup time is reduced from 3 ns to 2 ns, the clock-to-Q delay is only increased by 0.61 percent. However, when the flipflop setup time is further reduced from 2 ns to 1 ns, the clock-to-Q delay is increased by 4%. Thus, in the current example, the largest setup time in the range of setup times would be equal to 2 ns.

The parameter values used to characterize the clock-to-Q delay of a flipflop also include a number of load capacitance values, over a range of load capacitance values, and a number of clock rise times, over a range of clock rise times. Thus, as shown in FIG. 8, method 800 moves from 810 to 812, where a first load capacitance value and a first clock rise time value are selected. Using the two selected values, method 800 performs two circuit simulations of the flipflop, in order to measure and record the flipflop clock-to-Q delay time Tprop, for the cases of input data rising and input data falling. Furthermore, the risetime and falltime, for the Q output of the flipflop, are also measured and recorded during these two circuit simulations.

Method 800 then moves to select, for example, a different combination of input parameters, and then repeats the above steps. This process continues until the clock-to-Q delay Tprop, and the risetime and falltime for the Q output of the flipflop, have been measured and recorded, for each possible combination of input parameter values. The input parameter values include discrete values for process, voltage, temperature, load capacitance, clock risetime, input data risetime, input data falltime, setup time presented to the flipflop and hold time presented to the flipflop.

As stated above, the current 3D clock-to-Q timing model can be used to generate the entire clock-to-Q delay curve, including the flat portion and the steep portion, where the presented setup time lies between 0.622 ns and 1 ns. Thus, although a setup time difference of only 0.378 ns (1ns−0.622ns) appears to be a small difference, this difference can be of major importance, as illustrated by the following two examples.

A first example is a relatively high speed application, where the clock frequency is equal to 1 Ghz, and the clock period is equal to 1 ns. Thus, according to the prior-art clock-to-Q timing examples described above, if the flipflop is presented with a setup time of 0.9 ns, it would not be useable because its minimum required setup time is 1 ns.

However, according to the 3D clock-to-Q timing model of the current invention, if the flipflop is presented with a setup time of 0.9 ns, its clock-to-Q delay would be equal to 0.359 ns, which leaves 0.641 ns (1ns−0.359ns) for the propagation delay through other logic gates. In other words, the flipflop would be useable in this high speed application.

A second example is a low speed application, where the clock frequency is only equal to 100 Mhz, and the clock period is equal to 10 ns. Thus, according to the prior-art clock-to-Q timing examples described above, if the flipflop is presented with a setup time of 0.625 ns, it would not be useable because its minimum required setup time is 1 ns.

However, according to the 3D clock-to-Q timing model of the current invention, if the flipflop is presented with a setup time of 0.625 ns, its clock-to-Q delay would be equal to 1.23 ns, which leaves 8.77 ns (10ns−1.23ns) for the propagation delay through other logic gates. In other words, the flipflop would be useable in this low speed application, even though the setup time presented to the flipflop (0.625ns) is quite close to 0.622 ns, which is the setup time where the flipflop fails to change state.

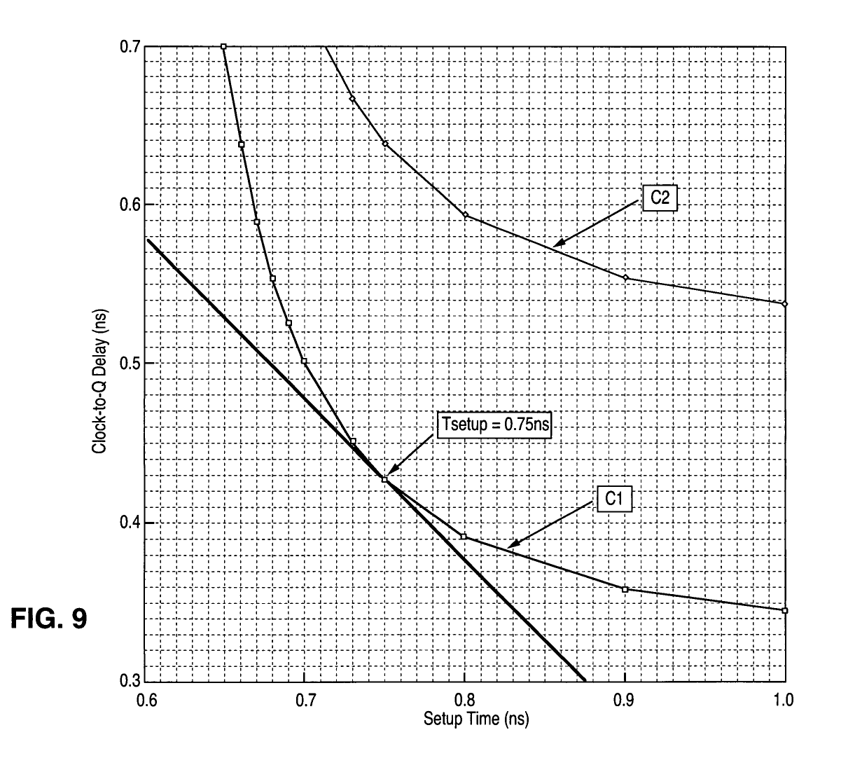

In accordance with the present invention, FIG. 9 shows a zoomed-in version of the C1 and C2 curves shown in FIG. 7. Therefore, the horizontal axis in FIG. 9 goes from 0.6 ns to 1 ns, whereas the horizontal axis in FIG. 7 goes from 0 ns to 10 ns.

When a chip timing analysis is being performed, allowing decreased setup times for the flipflops is highly desirable, because it eases the burden of meeting the timing requirements for any given logic path that includes a flipflop. However, as shown in FIG. 9, when the setup time presented to a flipflop is decreased, the flipflop clock-to-Q delay will be increased. Thus, during a chip timing analysis, it often becomes necessary to make a tradeoff between decreased flipflop setup time and increased flipflop clock-to-Q delay. Furthermore, for any given logic path that contains a flipflop, the optimum point of this tradeoff will occur where the sum of the setup time and the clock-to-Q delay is minimum. Thus a method of obtaining this minimum will now be described.

Referring to FIG. 9, a straight line, which has a slope of −1, is drawn tangent to the C1 curve. Moreover, this line intersects the C1 curve at a setup time value of 0.75 ns. Thus, for setup times greater than 0.75 ns, the sum of the setup time and the clock-to-Q delay will decrease as the setup time is decreased. Conversely, for setup times less than 0.75 ns, the sum of the setup time and the clock-to-Q delay will increase as the setup time is decreased. Therefore, in the FIG. 9 example, the optimum tradeoff between reduced setup time and increased clock-to-Q delay occurs at a setup time value of 0.75 ns.

It is important to note that the 0.75 ns setup time value obtained above is 0.25 ns less than the 1 ns setup time required by the prior-art 2-dimensional flipflop timing model. In other words, in the current example, the setup time has been reduced by 25%, by utilizing the current invention. Of course, in those cases where the clock-to-Q delay is not critical (i.e. it does not have to be minimal), the setup time can be further reduced below 0.75 ns. However, as shown in FIG. 7, the setup time can never be reduced below 0.622 ns, because the flipflop will fail to change state.

Those skilled in the art will appreciate that the optimum point in the tradeoff between reduced setup time and increased clock-to-Q delay can be obtained by alternate means. For example, the optimum setup time can be obtained by simply differentiating the C1 curve and choosing the setup time value where the differentiated curve value is equal to −1.

In summary, the 3-dimensional flipflop timing model of the present invention allows a flipflop to be presented with a smaller setup time in comparison to the prior-art 2-dimensional timing model. Because of this, fewer timing errors will be encountered during a chip timing analysis, and fewer timing errors will have to be fixed. In other words, the user can often avoid redesigning logic that fails to meet its timing specs, saving valuable design time. Furthermore, in many cases, the user can also avoid the necessity of using larger standard cells that employ larger transistor sizes. As a consequence, chip size and chip power dissipation can be reduced.

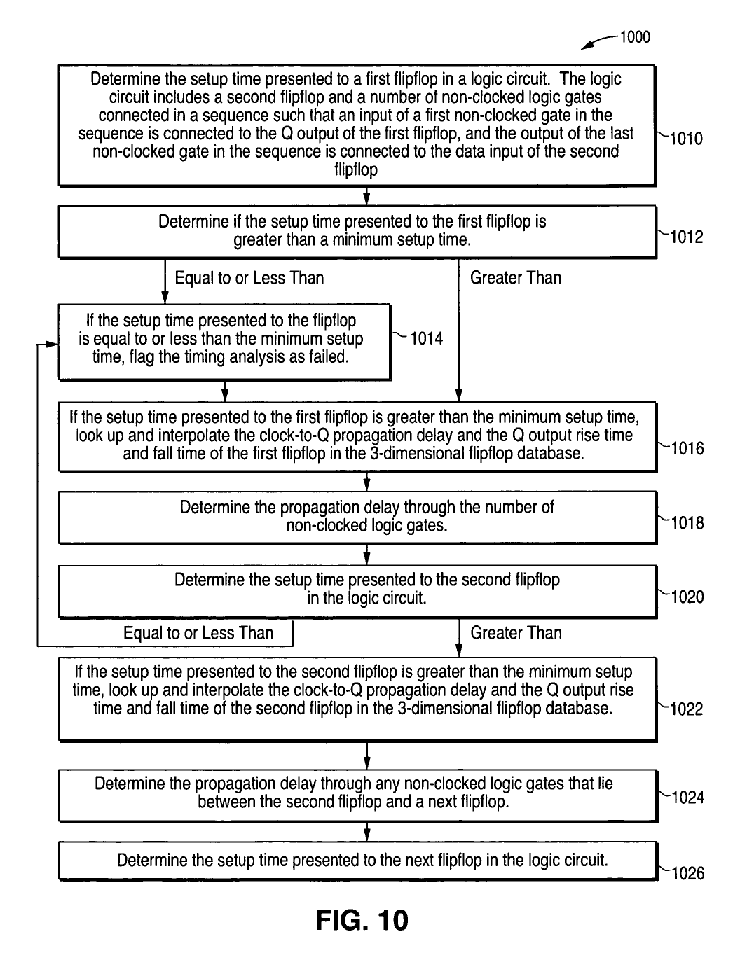

In accordance with the present invention, FIG. 10 shows a flow chart that illustrates an example of a method 1000, of determining the clock-to-Q delay of a flipflop. As shown in FIG. 10, method 1000 begins at 1010 by determining the setup time presented to a first flipflop in a logic circuit.

In this example, the logic circuit also includes a second flipflop and a number of non-clocked logic gates connected in a sequence such that an input of a first non-clocked gate in the sequence is connected to the Q output of the first flipflop, and the output of the last non-clocked gate in the sequence is connected to the data input of the second flipflop.

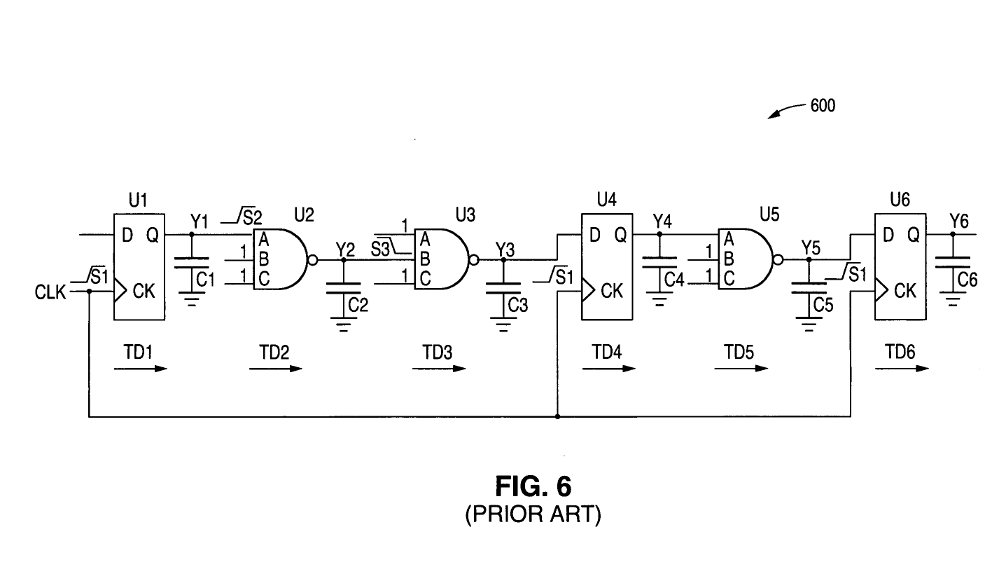

For example, FIG. 6 can be used to illustrate the logic circuit, with flipflop U1 representing the first flipflop, gates U2 and U3 representing the number of non-clocked logic gates, and flipflop U4 representing the second flipflop. In the FIG. 6 example, the setup time presented to flipflop U1 is determined by subtracting the clock arrival time from the data arrival time.

After this, method 1000 next moves to 1012 to determine if the setup time presented to the first flipflop is greater than a minimum setup time. In the examples shown in FIGS. 7 and 9, method 1000 moves to 1012 to determine if the setup time presented to the first flipflop is greater than 0.622 ns.

If the setup time presented to the first flipflop is equal to or less than the minimum setup time, method 1000 moves to 1014 where the timing analysis is flagged as failed. On the other hand, if the setup time presented to the first flipflop is greater than the minimum setup time, method 1000 moves to 1016 to look up and interpolate the clock-to-Q propagation delay and the Q output rise time and fall time of the first flipflop, in the 3-dimensional flipflop database of the present invention.

For example, referring to FIG. 6, the clock-to-Q propagation delay through the first flipflop U1 is based on three input parameters: the setup time presented to flipflop U1, the rise time of the clock signal (S1), and the value of capacitor C1. If the setup time presented to the flipflop U1 is greater than the minimum value (e.g. 0.622 ns), then these values are used to look up and interpolate the clock-to-Q propagation delay TD1 in the 3D flipflop database of the present invention. In addition, the rise time of the signal (S2) generated by the Q output of flipflop U1 is also looked up and interpolated in the flipflop database.

Next, method 1000 moves to 1018 to determine the propagation delay through a number of non-clocked logic gates. In the FIG. 6 example, the propagation delays TD2 and TD3 are next determined. To determine the propagation delay TD2, the rise time of the signal (S2) and the value of capacitor C2 must be utilized. As described, the rise time of the clock signal (S2) was determined when the clock-to-Q propagation delay of flipflop U1 was determined in the 3-dimensional database of the present invention. These values are then used to look up and interpolate the propagation delay TD2 in a NAND gate database. In addition, the fall time of the signal (S3), generated by the output of NAND gate U2, is also looked up and interpolated.

Next, the propagation delay TD3 of NAND gate U3 is determined. To determine the propagation delay TD3, the fall time of the clock signal (S3) and the value of capacitor C3 must be utilized. As described, the fall time of the clock signal (S3) was looked up and interpolated when the propagation delay of NAND gate U2 was determined. These values are then used to look up and interpolate the propagation delay TD3 in the NAND gate database.

Following this, method 1000 moves to 1020, to determine the setup time presented to the second flipflop U4 in the logic circuit. In the FIG. 6 example, the setup time presented to flipflop U4 is determined by subtracting the clock arrival time from the data arrival time (the total propagation delay TD1+TD2+TD3).

If the setup time presented to the second flipflop U4 is less than the minimum setup time for flipflop U4, method 1000 moves to 1014 where the timing analysis is flagged as failed. On the other hand, if the setup time presented to the second flipflop U4 is greater than the minimum setup time for flipflop U4, method 1000 moves to 1022 to look up and interpolate the clock-to-Q propagation delay, and the Q output rise time and fall time, of the second flipflop U4, in the 3-dimensional flipflop database of the present invention.

For example, referring to FIG. 6, the clock-to-Q propagation delay through the second flipflop U4 is based on three input parameters: the setup time presented to flipflop U4, the rise time of the clock signal (S1), and the value of capacitor C4. If the setup time presented to the flipflop U4 is greater than the minimum setup time for flipflop U4 (e.g. 0.622ns), then these values are used to look up and interpolate the clock-to-Q propagation delay TD4 in the 3D flipflop database of the present invention. In addition, the rise time and the fall time of the Q output of flipflop U4 is also looked up and interpolated in the flipflop database.

Following this, method 1000 moves to 1024 to determine the propagation delay through any non-clocked logic gates that lie between the second flipflop and the next flipflop. In the FIG. 6 example, method 1000 moves to 1024 to determine the propagation delay through logic gate U5.

Next, method 1000 moves to 1026, to determine the setup time presented to the next flipflop U6. In the FIG. 6 example, the setup time presented to flipflop U6 is determined by subtracting the clock arrival time from the data arrival time (the total propagation delay TD4+TD5). Method 1000 then continues in the same manner as described above, until the timing analysis has been completed for the entire chip.

Thus, one of the advantages of the present invention is that the present invention provides a calculation method that can reduce the required minimum setup time of a flipflop, without increasing the flipflop device sizes, the flipflop cell area or the flipflop power dissipation.

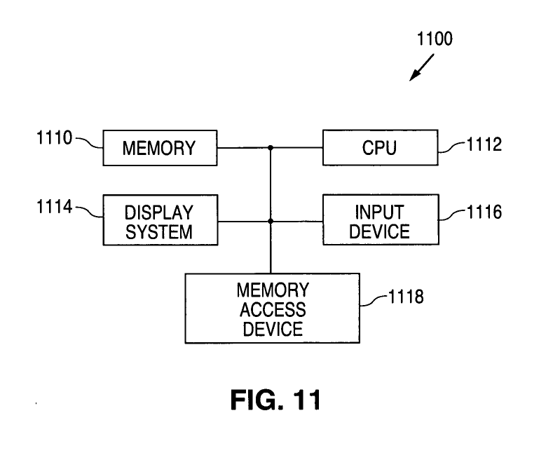

In accordance with the present invention, FIG. 11 shows a block diagram that illustrates an example of a computer 1100 in accordance with the present invention. As shown in FIG. 11, computer 1100 includes a memory 1110, and a central processing unit (CPU) 1112 that is connected to memory 1110. Memory 1110 can store data, an operating system, and a set of programming instructions. Furthermore, the operating system can be implemented with, for example, the Unix or Linux operating system, although other operating systems can be alternatively employed. The programming instructions, which are used to execute all or part of the methods of the present invention, can be written in C or C++, for example, although other programming languages can be alternatively employed.

CPU 1112, which can be implemented with, for example, a Core™ 2 Quad processor manufactured by Intel® or a similar processor, can operate upon programming instructions that implement all or part of the methods of the present invention. Furthermore, although only one processor has been described, the present invention can be implemented by utilizing multiple processors operating in parallel, in order to increase the program execution speed, and the computer's capacity to process large amounts of data.

In addition, computer 1100 can include a display system 1114, that is connected to CPU 1112. Display system 1114, which can be remotely located, allows images to be displayed to the user, which allow the user to interact with the program being executed. Computer 1100 can also include a user-input system 1116, that is connected to CPU 1112. Input system 1116, which can be remotely located, allows the user to interact with the computer program being executed.

Furthermore, computer 1100 can also include a memory access device 1118, such as a disk drive or a networking card, that is connected to memory 1110 and CPU 1112. Memory access device 1118 allows the data from memory 1110 or CPU 1112 to be transferred to a computer-readable medium or a networked computer. In addition, device 1118 allows the programming instructions to be transferred to memory 1110, from the computer-readable medium or a networked computer.

In an alternative embodiment of the present invention, hardware circuitry may be used in place of, or in combination with, software instructions, to implement all or part of an embodiment of the present invention. As a result, the present invention is not limited to any specific combination of hardware circuitry and/or software instructions.

In addition, embodiments of the present invention may be provided as a computer program, or as printed software instructions, or as software instructions on a machine accessible or machine readable medium. Furthermore, the software instructions on a machine accessible or machine readable medium may be used to program a computer system, or other electronic device.

Moreover, the machine-readable medium may include, but is not limited to, hard disks, floppy diskettes, optical disks, CD-ROMs, DVD disks, magneto-optical disks, or any other type of media/machine-readable medium suitable for storing and/or transmitting electronic instructions. Furthermore, the techniques described herein are not limited to any particular software configuration. Thus these techniques may find applicability in any computing or processing environment.

The terms “machine accessible medium” or “machine readable medium” used herein shall include any medium that is capable of storing, encoding, or transmitting a sequence of instructions for execution by machine, and that cause the machine to perform any one of the methods described herein. Furthermore, in the present state of the art, it is common to speak of software, in one form or another (e.g., program, procedure, process, application, module, unit, logic, and so on) as taking an action or causing a result. Such expressions are merely a shorthand way of stating that the execution of the software by a processing system causes the processing system to perform an action that produces a result.

It should be understood that the above descriptions are examples of the present invention, and that various alternatives of the invention described herein may be employed in practicing the invention. Therefore, it is intended that the following claims define the scope of the invention and that structures and methods within the scope of these claims and their equivalents be covered thereby.

What is claimed is:

1. A method of determining a flipflop propagation delay time comprising:
assigning a setup time to a first flipflop in a logic circuit, the logic circuit including a second flipflop and a number of non-clocked logic gates connected in a sequence such that an input of a first non-clocked gate in the sequence is connected to a Q output of the first flipflop, and an output of a last non-clocked gate in the sequence is connected to a data input of the second flipflop;
determining a total propagation delay of a data signal through the first flipflop and the number of non-clocked gates;
based on the total propagation delay and a clock period, determining a setup time presented to the second flipflop; and
looking up a clock-to-Q propagation delay of the second flipflop based on the setup time presented to the second flipflop.

2. The method of claim 1 and further comprising, when the clock-to-Q propagation delay of the second flipflop is greater than a maximum value, flagging a timing analysis as failed.

3. The method of claim 2 wherein the maximum value is a value that is substantially greater than a clock-to-Q propagation value that remains substantially constant over a range of setup times.

4. The method of claim 1 and further comprising, when the clock-to-Q propagation delay of the second flipflop is less than a maximum value, assigning the setup time presented to the second flipflop to the second flipflop.

5. The method of claim 4 wherein the maximum value is a value that is substantially greater than a clock-to-Q propagation value that remains substantially constant over a range of setup times.

6. The method of claim 5 wherein the clock-to-Q propagation delay of the second flipflop is looked up in a table.

7. The method of claim 6 wherein the table is populated by selecting:
a number of setup times over a range of setup times that extend from a point of infinity to a point where changes in the setup time cause no change in the clock-to-Q propagation delay;
a number of capacitance values over a range of capacitance values; and
a number of clock rise times over a range of clock rise times.

8. The method of claim 7 wherein the table is further populated by:
selecting a first capacitance from the number of capacitance values, and a first clock rise time from the number of clock rise times; and
for each of the number of setup times, testing a flipflop to measure, and record a clock-to-Q propagation delay time and an rising/falling edge time for the Q output of the flipflop.

9. A machine-readable medium having stored thereon sequences of instructions, the sequences of instructions including instructions which, when executed by a processor, causes the processor to perform:
assigning a setup time to a first flipflop in a logic circuit, the logic circuit including a second flipflop and a number of non-clocked logic gates connected in a sequence such that an input of a first non-clocked gate in the sequence is connected to a Q output of the first flipflop, and an output of a last non-clocked gate in the sequence is connected to a data input of the second flipflop;
determining a total propagation delay of a data signal through the first flipflop and the number of non-clocked gates;
based on the total propagation delay and a clock period, determining a setup time presented to the second flipflop; and
looking up a clock-to-Q propagation delay of the second flipflop based on the setup time presented to the second flipflop.

10. The machine-readable medium of claim 9 and further including instructions which, when executed by a processor, causes the processor to perform, when the clock-to-Q propagation delay of the second flipflop is greater than a maximum value, flagging a timing analysis as failed.

11. The machine-readable medium of claim 10 wherein the maximum value is a value that is substantially greater than a clock-to-Q propagation value that remains substantially constant over a range of setup times.

12. The machine-readable medium of claim 9 and further including instructions which, when executed by a processor, causes the processor to perform, when the clock-to-Q propagation delay of the second flipflop is less than a maximum value, assigning the setup time presented to the second flipflop to the second flipflop.

13. The machine-readable medium of claim 12 wherein the maximum value is a value that is substantially greater than a clock-to-Q propagation value that remains substantially constant over a range of setup times.

14. The machine-readable medium of claim 13 wherein the clock-to-Q propagation delay of the second flipflop is looked up in a table.

15. The machine-readable medium of claim 14 wherein the table is populated by selecting:
a number of setup times over a range of setup times that extend from a point of infinity to a point where changes in the setup time cause no change in the clock-to-Q propagation delay;
a number of capacitance values over a range of capacitance values; and
a number of clock rise times over a range of clock rise times.

16. The machine-readable medium of claim 15 wherein the table is further populated by:
selecting a first capacitance from the number of capacitance values, and a first clock rise time from the number of clock rise times; and
for each of the number of setup times, testing, measuring, and recording a clock-to-Q propagation delay time and an rising/falling edge time for the Q output of the flipflop.
